(19) United States
(12) Patent Application Publication
(10) Pub. No.: US 2009/0120783 A1
(43) Pub. Date: May 14, 2009

(54) Securing device for a sputtering source

(75) Inventor: Gerald Eschendorff, TE Venlo (NL)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Sulzer Metco AG, Wohlen (CH)

(21) Appl. No.: 11/724,048

(22) Filed: Mar. 13, 2007

(30) Foreign Application Priority Data
Mar. 16, 2006 (EP) 06405118.8

(51) Int. Cl. C23C 14/34

(52) U.S. Cl. 204/192.12; 204/298.15

(57) ABSTRACT

A securing device for a sputtering source in a sputtering space includes a current transmitting means (2, 10, 13, 15, 16, 17, 18) of electrically and thermally conductive material for the conducting of a current to the sputtering source and also a screening means (1, 4, 5, 6, 12) for the screening of the current transmitting means from the sputtering space, so that the current transmitting means can be electrically insulated from the sputtering space, characterised in that temperature resistant means (1, 5) are provided to guarantee a temperature resistance and a resistance to electrical discharges of the securing device, in particular at temperatures up to 1150° C.

This application claims the priority of European Patent Application No. 06405118.8, dated Mar. 16, 2006, the disclosure of which is incorporated herein by reference.

Sputtering sources for the HS-PVD coating method, also known as the gas flow sputtering method, are exposed to temperatures between 900° C. and 1150° C. during operation under vacuum conditions. Sputtering sources of this kind are secured in the interior of a closable container, so that a sputtering space forms. The closable container forms a vacuum chamber. The sputtering source is located in this vacuum chamber. The sputtering source includes at least one target or one target segment, which contains the coating material. The target or target segment is attached to a cooling body. The attachment of the target or the target segment takes place by means of a screw connection or a plug connection or a combination of both kinds of connections. The cooling body is made as a block of thermally conductive material, in which passages for the circulation of a coolant are arranged. The cooling body is secured on an external wall, which is facing away from the target or the target segments. This external wall is the outer boundary of the sputtering source. A securing device is mounted on this external wall for the introduction of an electrical current into the sputtering source. A securing device of this kind is known from the pre-amble of claim 1. A sensing device for the feeding of an electrical current into a sputtering source includes a current transmitting means of electrically conductive material for the conduction of a current to the sputtering source and also a screening means for screening of the current transporting means from the sputtering space outside of the vacuum chamber, so that the current transporting means is electrically insulated from the sputtering space.

Gas flow sputtering sources with a securing device are known from the prior art, which as screening means contain a cover female connector made of a hard plastic material. The screening means can, in particular, be manufactured from POM. POM is termed Ultraform® by BASF. The Utraform standard brands have a narrow range of melting temperatures 164°-168° C. Up to a temperature close to this range of melting temperatures moulded parts made of Ultraform can be thermally stressed for a short time, without damage to the material occurring. The problem results from this that the thermal stability of this class of plastics no longer exists for the temperature range aimed at. As a result the use of this material as a screening means results in carbonisation and to melting of the insulation. As a consequence high energy glow discharges arise, which can lead to the destruction of the securing device.

A further problem for the securing device from the prior art is represented by the operation under vacuum conditions. The installation of the securing device takes place in the atmospheric region while the coating method takes place in a vacuum. The current carrying means and the screening means can separate from one another under vacuum conditions. The cause can, on the one hand, lie in the above mentioned thermal loading and the different thermal expansion coefficients of the material combinations used, and can also be brought about by the suction pressure, which is produced by the suction effect of the vacuum generating device.

If currents of up to 40 A at a power density of up to 40/cm² target are applied to the sputtering source, the screening means from the prior art is only suitable for short coating times since the above-mentioned problems can arise in operation.

The object of the invention is thus the increase of the lifetime of the securing device, in particular of the screening means for the sputtering source at a high thermal load and/or high power density, in particular with the use in a HS-PVD coating method or a gas flow sputtering method. The gas flow sputtering method can not only be used for the coating of components with a metallic layer but also for the coating with a ceramic layer. Such metallic and/or ceramic layers are in particular needed for components which are exposed to temperatures over 1000° in operation, such as components for gas turbines, for example turbine blades. In the gas flow sputtering method an inert gas or a reactive gas is required, depending on the composition of the layer formation, in order to sputter the coating material from the coating source. The gas atoms strike the coating material, which is provided on so-called targets in the coating source at a high speed. The gas is present in a state of high energy, this is in particular an ionised plasma, so that the gas ions can knock atoms out of the target surface. The atoms are moved with the flow of gas and conducted in the direction of the component to be coated. In reactive gas flow sputtering, they can be brought into contact with a reactive gas, in particular an oxygen-containing gas, on the way to the component, whereby chemical reactions take place in the gas phase and/or on the component surface.

The way of satisfying the object includes the electrical coupling in of the sputtering source by an electrically conductive securing device to an energy source, which is equipped with high temperature resistant means.

The way the object is satisfied results in the securing device comprising temperature resistant means, which guarantee a use of the coating source for power densities in particular up to 220 W/cm² and in temperature ranges of up to 1150° C.

The securing device comprises therefore a coupling to an energy source, in particular a current source for supply of a sputtering source, in particular a hollow cathode sputtering source, with energy from the energy source. An essential aspect of the securing device is therefore its multifunctionality as securing device for the fixation of a sputtering source, as electrically conductive connection by means of the electrical coupling to the energy source, as well as screening means for screening and insulating the sputtering source electrically and thermally in a sputtering space with exception of the previously mentioned electrical connection. This electrical and thermal screening comprises a dark space screening, a screening against short circuiting as well as a screening and insulation against thermal overlaod.

The temperature resistant means include a fillable hollow body and/or at least one electrically insulating layer. In an advantageous embodiment a hollow body of this kind is manufactured from stainless steel.

According to an advantageous embodiment the insulating layer is arranged in the interior of the hollow body, whereby the current transmitting means can be at least partly surrounded. The hollow body can be formed as a hollow cylinder, can however also have a cuboid or parallelpiped shaped surface, or polygonal, in particular hexagonal jacket surfaces, which can also be formed as engagement surfaces for a tool or can be formed as a handle. The current transmitting means includes a solid body, in particular a solid cylinder, which includes a securing possibility at one end to a sputtering source on the outer wall. This securing possibility can include a screw connection. The solid body is inserted into the hollow body, then the insulating layer is poured between the solid body and the hollow body. On the opposite end of the solid body is located a connection for an electrically conductive rod, which includes, in particular, a screw connection. The electrically conductive rod is at least partly enclosed by a plastic hose. The end of the electrically conductive rod opposite to the screw connection is formed as a plug element. The plug element engages in an electrically conductive core of a female connector. This electrically conductive core is likewise surrounded by a layer of electrically non-conductive material. A connecting element, an angled plug, a further cable and a further female connector are connected to the female connector.

The insulating layer contains proportions of a ceramic powder, and also an adhesive, with a stone powder, in particular steatite being used and the adhesive including an epoxy resin glue, in particular a two component glue and/or the proportions of ceramic powder and adhesive are in a range around 50% by weight.

Steatite is a ceramic material on the basis of natural raw materials and is composed of the main component soapstone (Mg(Si₄O₁₀)(OH)₂, a natural magnesium silicate and of additions of clay and feldspar or barium carbonate. Steatite is normally densely sintered. The nature of the flux influences the electrical characteristics of the material and leads to the differentiation between normal steatite and special steatite, which is also called high frequency steatite. In international standardisation special steatite is listed as steatite with a low loss factor and is not only suitable for low-loss high frequency components, but is also very good for the manufacture of components with thin and uniform wall thicknesses due to its good machinability. In this way mechanical stresses caused, in particular, by heat can be overcome. Due to its low shrinkage, the material is particularly suitable for the economic manufacture of components with tight tolerances and for the dry pressing method as a result of the raw material base being low in abrasion and gentle to tools. Due to the low shrinkage steatite has proved to be a particularly suitable material for components exposed to changing temperature loads, particularly because of the high temperature loading in a gas flow sputtering process. A durable bond is achieved in combination with the adhesive, through the low shrinkage there is no alteration in the structure of adhesive and steatite, so that there is no break-down of the securing device through micro cracks. The hollow body and the solid body are not only joined together in a lasting manner by the insulating layer, but they can also be manufactured with tight tolerances. Since the external wall of the sputtering source can heat up in a long term effect and short-term discharges can lead to carbonisation of the insulating layer, the chosen mixture of steatite powder with synthetic resin has proved to be particularly advantageous.

The current take up of the sputtering source amounts, when using the described securing device, to up to 150 A in particular.

The power density of the sputtering source when using the securing device amounts in particular to up to 220 W/cm² of target area.

The current transmitting means of the securing device includes a contact sleeve for the connection of a cable for the conducting of electrical current to the cooling body of the coating source, wherein the contact sleeve is mounted at a coolant connection, which is in direct electrical contact with the cooling body of the coating source.

The securing device is used in a coating plant, it is particularly suitable for a coating plant for metallic and reactive gas flow sputtering.

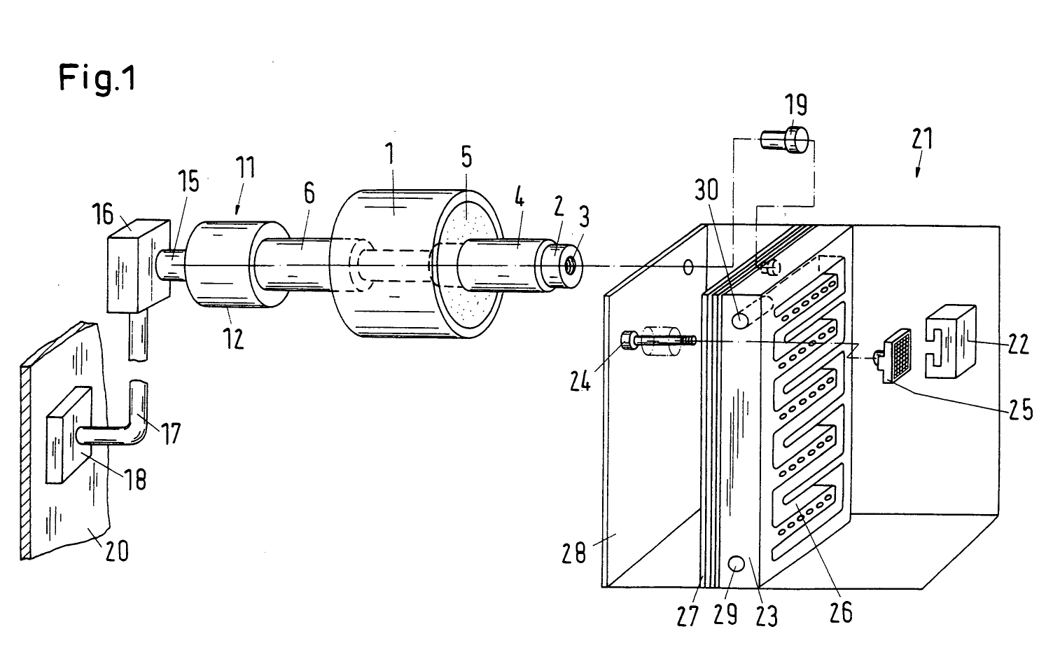

FIG. 1 shows the arrangement of the securing device in the sputtering space

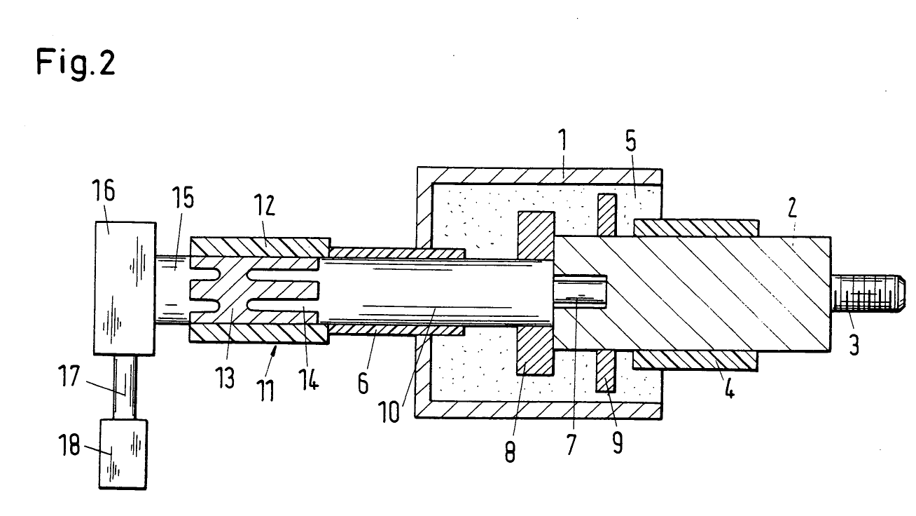

FIG. 2 is a section through the securing device

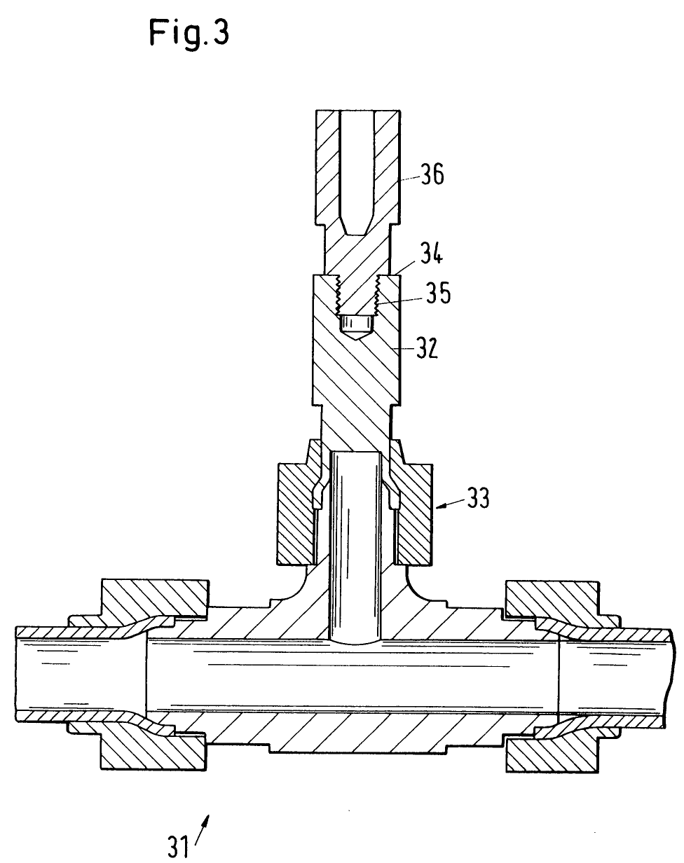

FIG. 3 is a further embodiment of a securing device

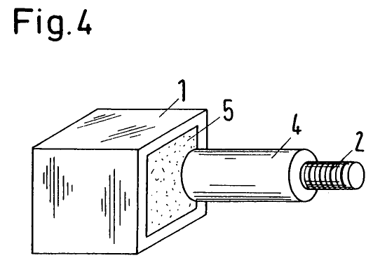

FIG. 4 is a further embodiment of a securing device.

In accordance with FIG. 1 sputtering sources for the HS-PVD coating method are secured in the interior of a closable container 20, so that a sputtering space forms. The closable container 20 is mostly formed as a vacuum chamber. The sputtering source 21 is located in this vacuum chamber. The sputtering source includes at least one target or a target segment 22, which contains the coating material. The target or target segment 22 is mounted on a cooling body 23. The mounting of the target or target segment takes place via a screw connection 24 or a plug connection 25 or a combination of both types of connection. The cooling body 23 is designed as a block of thermally conductive material, in which passages 26 for the circulation of a coolant are arranged. The cooling body is secured on an external wall 27 on the side, which is facing away from the target or the target segment. This external wall is the outer boundary of the sputtering source. The securing device in accordance with the invention is mounted on this external wall for the introduction of an electrical current into the sputtering source 21. The sputtering source 21 is electrically screened from the sputtering space by an insulating zone 28. The insulating zone 28 is shown in FIG. 1 next to the plate-like element. The insulating zone 28 can be formed as a vacuum, with the spacing between the oppositely disposed walls of the hollow space preventing discharges occurring between the sputtering source 21 and the container wall of the vacuum chamber (20). The distance between the sputtering source and the container wall amounts to a few millimetres in particular and should not fall below this value at any point because local voltage peaks can build up precisely at these points, which lead to spontaneous discharges, which can cause damage to the vacuum container or the sputtering source.

The securing device for the sputtering source 21 in a sputtering space includes in accordance with FIG. 2 a current transmitting means (2, 10, 13, 15, 16, 17, 18) of electrically and thermally conductive material for the conducting of a current to the sputtering source 21 and also a screening means (1, 4, 5, 6, 12) for the screening of the current transmitting means from the sputtering space. The current transmitting means can be electrically insulated from the sputtering space. Temperature resistant means (1, 5) are provided to guarantee a temperature resistance of the securing device, in particular up to 1150° C. The temperature resistant means include a hollow body 1 and/or at least one electrically insulating layer 5. A hollow body of this kind is manufactured from stainless steel in an advantageous embodiment. According to an advantageous embodiment the insulating layer 5 is arranged in the interior of the hollow body 1, by which means the current transmitting means (2, 10, 13, 15, 16, 17, 18) can be surrounded at least in part. The current transmitting means includes a solid body, in particular a solid cylinder 2, which contains a securing possibility 3 for the target holder of a sputtering source on one end. The solid cylinder 2 establishes the electrical contact with the target holder, so that current can be transmitted into the target holder to the targets or target segments. At the beginning the solid cylinder 2 is screwed onto the target holder together with the plastic hose 4.

This securing possibility 3 can include a screw connection. The solid cylinder 2 is inserted into the hollow body 1, at least partly, then the insulating layer 5 is poured in between the solid cylinder 2 and the hollow body 1. Assembly aids (8, 9) are used for the assembly and for the filling with the adhesive and the powder, which also make the filling with the mixture of adhesive and powder possible, which has poor flow characteristics due to its high viscosity. However, before the hardening of the adhesive takes place, the filling procedure and the distribution of the adhesive in the interior of the hollow body has to be completed. The part of the solid cylinder 2, which extends beyond the hollow body 1, is at least partly encased by a plastic hose 4. The plastic hose consists of a polyamide in particular. Since the whole target holder of the sputtering source is water-cooled, and the screw connection is located on the rear side of the source (i.e. is both thermally completely insulated and cooled) in other words outside the high temperature range, the use of plastic hoses is permissible when the occurrence of electrical glow discharges can be ruled out in this connection.

A connection 7 for an electrically conductive rod 10, which includes in particular a screw connection, is located at the opposite end of the solid cylinder 2. The electrically conductive rod 10 is at least partly encased by a plastic hose 6. The end of the electrically conductive rod lying opposite the screw connection is formed as a plug element 14. The plug element 14 engages into an electrically conductive core 13 of a female connector 11. The electrically conductive core 13 of the female connector 11 is surrounded by a layer of electrically non-conductive material 12. A connection element 15, which can be formed as a cable, an angled plug 16, a further cable 17 and a further female connector 18 are connected to the female connector 11. The part of the screw connection 3, which is in particular formed as an M8 thread is screwed firmly to the outer wall 27 of the sputtering source 21. During assembly and/or dismantling of the sputtering source 21, when the coating material is used up and the targets or target segments 22 are exchanged or maintenance measures are necessary, the angled plug (15, 16) is plugged into or unplugged from the female connector (11, 12, 13). The cable 17 is in particular firmly connected to the female connector 18 with a cable length of approximately 1.5 to 3 metres inside the vacuum chamber, since, under some circumstances, the source is completely installed in the vacuum chamber. The female connector 28 is connected to a vacuum current feed-through which is located at the inside of the vacuum chamber and thus serves for the transmitting of current from the generator into the vacuum chamber 20. This construction has the advantage that one can establish or separate the electrical connection at any time and without a great deal of time and effort.

The hollow body 1 and the massive cylinder 2 are manufactured from materials of sufficient mechanical strength which preferably do not contain any pollutants. Pollutants, such as, for example, Zn, Sn and Pb, can lead to a lowering of the melting point. Thus the hollow body 1 and the solid cylinder 2 are therefore preferably made of stainless steel or of Hasteloy.

A further embodiment for the securing device is illustrated in FIG. 3. The current connection in accordance with this embodiment takes place at an already present coolant connection 31. The coolant connection 31 is located at the coolant inlet 29 shown in FIG. 1 or at the coolant outlet 30 of the cooling body 23. The cooling body 6 is made of material of good thermal and electrical conductivity, in particular of copper, low alloy copper, nickel or of an alloy containing copper and/or nickel. The existing coolant connection 31 is likewise manufactured from a temperature resistant material of good electrical conductivity, so that the coolant connection 31 can also be used for the feeding of the electrical current into the cooling body of the coating source. For this purpose a connection element 32 is screwed to the screw connector 33, with the connection element 32 likewise consisting of a metallic material. The connection element 32 includes at the end 34, which lies opposite the end clamped in the screw connector, an internal thread 35 for receiving a contact sleeve 36. The contact sleeve 36 serves to receive a not illustrated contact plug, which can be plugged into the blind bore 37. A cable leads from the contact plug to a further female connector in the container wall of the vacuum container, which contains the coating source. The connection to a current source located outside of the vacuum chamber takes place via this female connector.

FIG. 4 shows a further embodiment of the securing device, which has no current connection. The securing device in accordance with FIG. 4 includes a current transmitting means (2) made of electrically and thermally conductive material, which is suitable to conduct current to the sputtering source, and a screening means (1, 4, 5) for screening of the current transmitting means, with which the current transmitting means (1, 4, 5) can be electrically insulated from the sputtering chamber. Temperature resistant means (1, 5) are provided in order to guarantee a temperature resistance of the securing device, in particular up to 1150°.

The temperature-resistant means include a hollow body 1 and/or at least one electrically insulating layer 5. A hollow body 1 is manufactured from stainless steel in an advantageous embodiment. The insulating layer 5 is arranged in the interior of the hollow body 1, in accordance with an advantageous embodiment, by which means the current transmitting means 2 can be surrounded completely. The current transmitting means 2 is not in electrical contact with the hollow body 1, which can be insulated from the current transmitting means in this case. The current transmitting means includes a solid body, in particular a solid cylinder 2, which has at one end a securing possibility 3 for the target holder, which is a component of a sputtering source. The solid cylinder 2 manufactures the electrical contact with the target holder, so that current can be transmitted into the target holder to the target or target segment arranged there. The solid cylinder 2 is initially screwed onto the target holder, together with the plastic hose 4. This securing possibility 3 can include a screw connection. The solid cylinder 2 is at least partly inserted into the hollow body 1, then the insulating layer 5 is poured between the solid cylinder 2 and the hollow body 1. For the assembly and the filling with the adhesive and of the powder not illustrated assembly aids are used in this embodiment, which also make possible the filling with a prepared mixture of adhesive and powder, which has poor flow characteristics due to its high viscosity. Before the hardening of the adhesive takes place, the filling process and the distribution of the adhesive in the interior of the hollow body have to be completed. The part of the solid cylinder 2, which extends beyond the hollow body 1, is at least partly enclosed by a plastic hose 4. The plastic hose is made of a polyamide in particular. Since the entire target holder of the sputtering source is water-cooled and the screw connection is located at the rear side of the source (i.e. both thermally completely insulated and cooled) in other words outside the high temperature region, the use of plastic hoses is permissible when one can exclude the occurrence of electrical glow discharges as in the previous embodiments.

### LIST

1. Hollow body
2. Massive body
3. Screwed connection
4. Plastic tube made of polyamide (electrical insulator)
5. Hardenable adhesive mixture
6. Plastic tube
7. Connection
8. Installation aid
9. Installation aid
10. Electrically conducting rod with connections
11. Female connector
12. Electrically non-conducting layer of the female connector
13. Electrically conducting core of the female connector
14. Plug element
15. Connection element
16. Angled plug
17. Cable
18. Female connector
19. Screw
20. Container, vacuum chamber
21. Sputtering source
22. Target or target segment
23. Cooling body
24. Screw connection
25. Plug connection
26. Channel
27. External wall
28 Insulating layer
29. Coolant inlet
30. Coolant outlet
31. Coolant connection
32. Connection element
33. Screw closure
34. End
35. Internal thread
36. Contact sleeve

1. A securing device for a sputtering source in a sputtering space including a current transmitting means (2, 10, 13, 15, 16, 17, 18) of electrically and thermally conductive material for the conducting of a current to the sputtering source and also a screening means (1, 4, 5, 6, 12) for the screening of the current transmitting means from the sputtering space, so that the current transmitting means can be electrically insulated from the sputtering space, characterised in that temperature resistant means (1, 5) are provided to guarantee a temperature resistance of the securing device, in particular up to 1150° C.

2. A securing device in accordance with claim 1, wherein the temperature resistant means include a fillable hollow body (1).

3. A securing device in accordance with claim 1, wherein the temperature resistant means include at least one electrically insulating layer (5).

4. A securing device in accordance with claim 3, wherein the insulating layer (5) is arranged in the interior of the fillable hollow body (1), whereby the current transmitting means (2, 10, 13, 15, 16, 17, 18) can be at least partly surrounded.

5. A securing device in accordance with claim 4, wherein the insulating layer (5) contains proportions of a ceramic powder, and also an adhesive, wherein the ceramic powder contains steatite in particular, and the adhesive includes an epoxy resin glue, in particular a two component glue and/or the proportions of ceramic powder and adhesive each amount to 50% by weight in particular.

6. A securing device in accordance with claim 1, wherein the power take up of the sputtering source amounts to up to 150 A in particular.

7. A securing device in accordance with claim 1, wherein the current density amounts to up to 220 W/cm² in particular.

8. A securing device in accordance with claim 1, wherein the current transmitting means includes a contact sleeve (36) for the connection of a cable for conducting electrical current to the cooling body (23) of the coating source and wherein the contact sleeve is mounted on a coolant connection (31), which is in direct electrical contact with the cooling body (23) of the coating source.

9. A coating plant with a securing device in accordance with claim 1.

10. The use of the securing device in a coating plant for reactive gas flow sputtering and/or metallic gas flow sputtering.
